(19) United States
(12) Patent Application Publication
(10) Pub. No.: US 2026/0005699 A1
(43) Pub. Date: Jan. 1, 2026

(54) System and Method for Calibrating ADC Nonlinearities With Trained Machine-Learning Model

(71) Applicant: Omni Design Technologies, Inc., Milpitas, CA (US)

(72) Inventor: Manar El-Chammas, Austin, TX (US)

(21) Appl. No.: 19/241,811

(22) Filed: Jun. 18, 2025

Related U.S. Application Data
(60) Provisional application No. 63/664,295, filed on Jun. 26, 2024.

(51) Int. Cl. H03M 1/10

(52) U.S. Cl. CPC H03M 1/1014

(57) ABSTRACT

A system includes a primary analog-to-digital converter (ADC) having an input electrically coupled to an input voltage, the primary ADC configured to sample the input voltage at a frequency and convert sampled input voltages to respective primary ADC digital outputs; and a trained calibration engine having an input electrically coupled to an output of the primary ADC, the trained calibration engine including a trained machine-learning (ML) model configured to correct each primary ADC digital output to a respective corrected digital output, the trained ML model having been trained with reference digital outputs from a reference ADC and training digital outputs from the primary ADC, the reference digital outputs representing ground-truth data for modeling the training digital outputs from the primary ADC.

### CROSS-REFERENCE TO RELATED APPLICATIONS

This application claims priority to U.S. Provisional Application No. 63/664,295, titled “System and Method for Calibrating ADC Nonlinearities With Trained Machine-Learning Model,” filed on Jun. 26, 2024, which is hereby incorporated by reference.

### TECHNICAL FIELD

This application relates generally to analog-to-digital converters.

### BACKGROUND

Calibration algorithms are often used to improve the performance of analog-to-digital converters (ADCs). These typically consist of an estimation and correction engine, with the estimation algorithm running either in the background or foreground (or some combination thereof). However, a drawback is that these calibration algorithms often require an understanding of the impairment or defect that is being corrected or compensated.

A lookup table (LUT), which contains entries for each output of the ADC, allows for a direct mapping of the ADC to a more linearized transfer function. For example, assume we have a 12-bit ADC. An LUT can contain 4096 entries (each with at least 12 bits), such that D_{OUT}=LUT[D_{ADC}], where LUT[ ] is the mapping function of the lookup table. The LUT is updated with values of a reference digital output D_{REF} in order to linearize the transfer function of the primary ADC.

An LUT can address various static nonlinearities but is not suited to address dynamic nonlinearities. While some dynamic nonlinearities can be addressed with LUTs, this is limited to knowing what the nonlinearity sources are.

### SUMMARY

Example embodiments described herein have innovative features, no single one of which is indispensable or solely responsible for their desirable attributes. The following description and drawings set forth certain illustrative implementations of the disclosure in detail, which are indicative of several exemplary ways in which the various principles of the disclosure may be carried out. The illustrative examples, however, are not exhaustive of the many possible embodiments of the disclosure. Without limiting the scope of the claims, some of the advantageous features will now be summarized. Other objects, advantages, and novel features of the disclosure will be set forth in the following detailed description of the disclosure when considered in conjunction with the drawings, which are intended to illustrate, not limit, the invention.

An aspect of the invention is directed to a system comprising a primary analog-to-digital converter (ADC) having an input electrically coupled to an input voltage, the primary ADC configured to sample the input voltage at a frequency and convert sampled input voltages to respective primary ADC digital outputs; and a trained calibration engine having an input electrically coupled to an output of the primary ADC, the trained calibration engine including a trained machine-learning (ML) model configured to correct each primary ADC digital output to a respective corrected digital output, the trained ML model having been trained with reference digital outputs from a reference ADC and training digital outputs from the primary ADC, the reference digital outputs representing ground-truth data for modeling the training digital outputs from the primary ADC.

In one or more embodiments, the reference ADC comprises a sigma-delta ADC. In one or more embodiments, the frequency of the primary ADC is higher than a frequency of the reference ADC. In one or more embodiments, the frequency of the primary ADC is about 50 times to about 1,000 higher than the frequency of the reference ADC. In one or more embodiments, the frequency of the primary ADC is about 1 gigasamples per second (GSPS) to about 100 GSPS.

In one or more embodiments, the trained ML model comprises a trained artificial neural network.

Another aspect of the invention is directed to a system comprising a primary analog-to-digital converter (ADC) having an input electrically coupled to an input voltage, the primary ADC configured to sample the input voltage at a first frequency and convert first sampled input voltages to respective primary ADC digital outputs; a reference ADC having an input electrically coupled to the input voltage, the reference ADC configured to sample the input voltage at a second frequency and convert second sampled input voltages to respective second ADC digital outputs; and a trained calibration engine having a first input electrically coupled to an output of the primary ADC and a second input electrically coupled to an output of the reference ADC, the trained calibration engine including a trained machine-learning (ML) model configured to correct the primary ADC digital output to a corrected digital output, the trained ML model having been trained with reference digital outputs from the reference ADC and training digital outputs from the primary ADC, the reference digital outputs representing ground-truth data for modeling the training digital outputs from the primary ADC, the trained calibration engine configured to update the trained ML model using the respective second ADC digital outputs.

In one or more embodiments, the reference ADC comprises a sigma-delta ADC.

In one or more embodiments, the first frequency of the primary ADC is higher than the second frequency of the reference ADC. In one or more embodiments, the first frequency of the primary ADC is about 50 times to about 1,000 higher than the second frequency of the reference ADC. In one or more embodiments, the first frequency of the primary ADC is about 1 gigasamples per second (GSPS) to about 100 GSPS.

In one or more embodiments, the trained ML model comprises a trained artificial neural network.

Another aspect of the invention is directed to a method for training a calibration engine for a primary analog-to-digital converter (ADC), comprising electrically connecting an input of the primary ADC to an input voltage, the primary ADC configured to sample the input voltage at a first frequency and convert first sampled input voltages to respective primary ADC digital outputs; electrically connecting an input of a reference ADC to the input voltage, the reference ADC configured to sample the input voltage at a second frequency and convert second sampled input voltages to respective reference ADC digital outputs; electrically connecting an output of the primary ADC to a first input of the calibration engine, the calibration engine including an untrained machine-learning (ML) model; electrically connecting an output of the reference ADC to a second input of the calibration engine; operating the primary and reference ADCs over an input-voltage range; feeding the respective primary ADC digital outputs to the calibration engine, the respective primary ADC digital outputs representing the input-voltage range; feeding the respective reference ADC digital outputs to the calibration engine, the respective reference ADC digital outputs representing the input-voltage range; and training the untrained ML model in the calibration engine using the respective primary ADC digital outputs and the respective reference ADC digital outputs, the respective reference ADC digital outputs representing ground-truth data for modeling the respective primary digital outputs from the primary ADC.

In one or more embodiments, the method further comprises producing the input voltage with a voltage source such that the input voltage is known. In one or more embodiments, the untrained ML model is trained using foreground calibration.

In one or more embodiments, the input voltage is unknown and the untrained ML model is trained using background calibration. In one or more embodiments, the reference ADC comprises a sigma-delta ADC. In one or more embodiments, the first frequency of the primary ADC is higher than the second frequency of the reference ADC. In one or more embodiments, the first frequency of the primary ADC is about 1 gigasamples per second (GSPS) to about 100 GSPS.

In one or more embodiments, the untrained ML model comprises an untrained artificial neural network.

### BRIEF DESCRIPTION OF THE DRAWINGS

For a fuller understanding of the nature and advantages of the concepts disclosed herein, reference is made to the detailed description of preferred embodiments and the accompanying drawings.

FIG. 1 is a block diagram of a system for training a calibration engine for an analog-to-digital converter (ADC) according to one or more embodiments.

FIG. 2A is a block diagram of a fully connected artificial neural network (ANN) according to one or more embodiments.

FIG. 2B is a detailed view of a portion of the block diagram shown in FIG. 2A according to one or more embodiments.

FIG. 3 is a block diagram of a system for performing an analog-to-digital conversion of an input voltage to a corrected digital output using a trained calibration engine according to one or more embodiments.

FIG. 4 is an example graph of the spurious-free dynamic range and signal-to-noise and distortion ratio convergence of a trained ANN according to one or more embodiments.

FIG. 5 is a block diagram of a system for performing an analog-to-digital conversion of an input voltage to a corrected digital output using a trained calibration engine according to one or more alternative embodiments.

FIG. 6 is a flow chart of a method for training a calibration engine for an ADC according to one or more embodiments.

FIG. 7 is a flow chart of a method for correcting a digital output of an ADC using a trained calibration engine according to one or more embodiments.

FIG. 8 is a flow chart of a method for correcting a digital output of an ADC using a trained calibration engine according to one or more alternative embodiments.

FIG. 9 is a block diagram of a computer having an untrained machine-learning (ML) model.

FIG. 10 is a block diagram of a computer having a trained ML model.

### DETAILED DESCRIPTION

A calibration engine having a machine-learning (ML) model is trained to calibrate and correct for known and unknown nonlinearities in the transfer function of an analog-to-digital converter (ADC). The trained ML model functions as a more general-purpose calibration engine that does not require the knowledge a priori of nonlinearities in an ADC, can cover more impairments (e.g., sources of nonlinearity), and can facilitate a more comprehensive correction scheme. An example of a trained ML model is a trained artificial neural network (ANN).

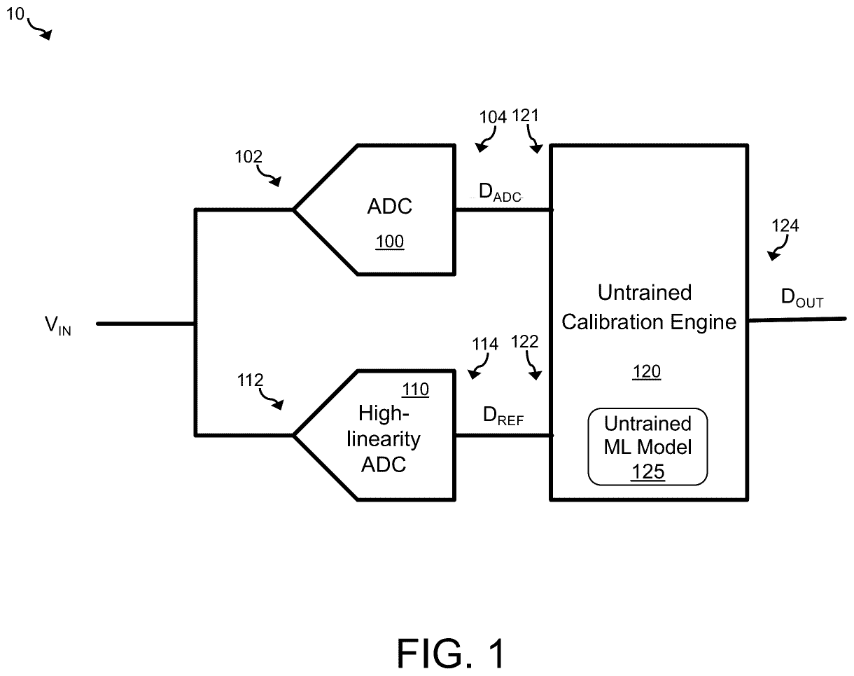

FIG. 1 is a block diagram of a system 10 for training a calibration engine for an ADC according to one or more embodiments. The system 10 includes a primary ADC 100, a reference ADC 110, and an untrained calibration engine 120. The primary ADC 100 and the reference ADC 110 have respective inputs 102, 112 (e.g., respective input terminals) that are electrically connected to an input voltage V_{IN}. The input voltage V_{IN} can be an alternating current (AC) voltage or a direct current (DC) voltage. The respective outputs (e.g., respective output terminals) 104, 114 of the primary and reference ADCs 100, 110 are electrically connected to respective inputs 121, 122 (e.g., first and second inputs) of the untrained calibration engine 120.

The primary ADC 100 is configured to sample the analog input voltage V_{IN} at a first frequency and to convert the sampled input voltage V_{IN} to a digital output D_{ADC} that represents the sampled input voltage V_{IN}. The primary ADC 100 is configured to operate at a relatively high frequency, such as in the range of about 1 GSPS (gigasamples per second) to about 100 GSPS or another frequency range. The digital output D_{ADC} of the primary ADC 100 may be used as an input in a larger circuit or electronic system (e.g., an electronic device such as a computer, a smartphone, a sensor, a television, or another electronic device).

The primary ADC 100 is less accurate than the reference ADC 110. Examples of the sources of error/inaccuracy of the primary ADC 100 can include fabrication errors, tolerance variations of components of the primary ADC 100, sampling clock jitter, supply voltage variation, and/or other sources. One or more of the sources of error/inaccuracy of the primary ADC 100 may be unknown and/or difficult to model.

The reference ADC 110 is configured to sample the analog input voltage V_{IN} at a second frequency and to convert the sampled input voltage V_{IN} to a digital output D_{REF} that represents the analog input voltage V_{IN}. The reference ADC 110 produces a highly linear and/or a highly accurate output that can used to calibrate the primary ADC 100. An example of a reference ADC 110 is a sigma-delta ADC. The reference ADC 110 should have dynamic and/or static metrics that are better than or equal to that/those of the primary ADC 100 after calibration. In one or more embodiments, the reference ADC 110 can have a spurious-free dynamic range (SFDR) that is greater than or equal to a target SFDR of the primary ADC 100 after calibration. For example, if the target SFDR of the primary ADC 100, after calibration, is 70 dB, then the reference ADC 110 should have an SFDR of at least 70 dB, such as 70 dB to 100 dB.

The reference ADC 110 can run at the same frequency as the primary ADC 100, but can also be configured to operate at lower frequencies than the primary ADC 100. In some embodiments, the first frequency of the primary ADC 100 can be about 50 times to about 1,000 times higher than the second frequency of the reference ADC 110. The low operating frequency of the reference ADC 110 can make it impractical for use in the larger circuit or electronic system to which the primary ADC 100 can be electrically coupled. In one or more embodiments, the primary and reference ADCs 100, 110 can run as the same frequency, but the reference ADC 110 can be power cycled to reduce overall power consumption.

The untrained calibration engine 120 receives as inputs 121, 122 the digital output D_{ADC} of the primary ADC 100 and the digital output D_{REF} of the reference ADC 110, respectively. The untrained calibration engine 120 is configured to train an untrained ML model 125, such as an ANN, to model the digital output D_{ADC} using the digital output D_{REF} as ground-truth data. The untrained calibration engine 120 and/or the untrained ML model 125 produces a digital output D_{OUT}, at an output 124 of the untrained calibration engine 120, based on the inputs 121, 122 D_{ADC} and D_{REF}, respectively, and the untrained ML model 125. The untrained ML model 125 is trained to correct D_{ADC} such that, when trained, the digital output D_{OUT} represents a corrected (e.g., more linear) output of the primary ADC 100.

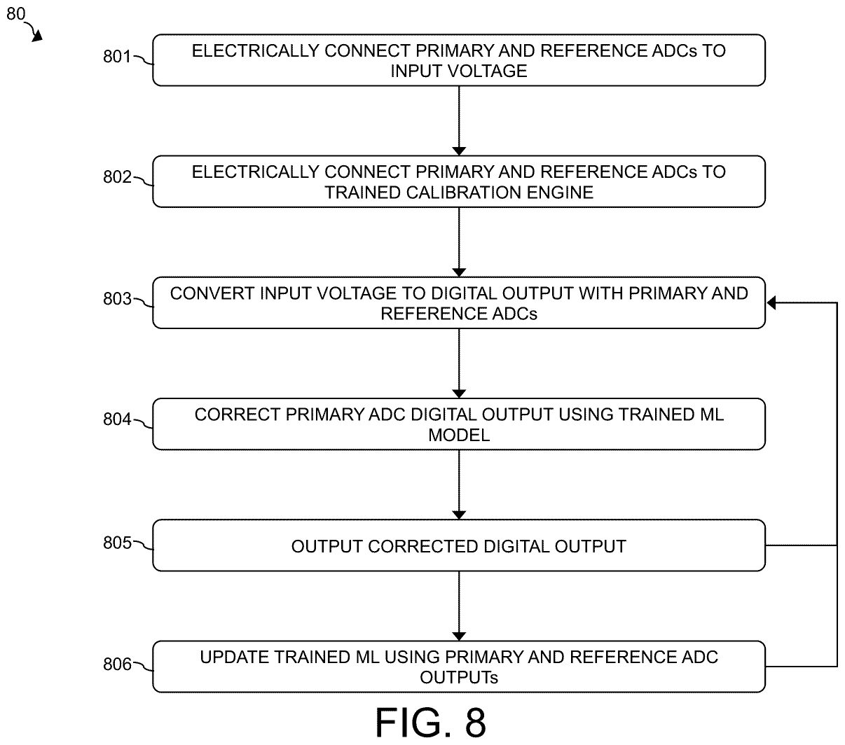

In one or more embodiments, the untrained calibration engine 120 and/or the untrained ML model 125 can be implemented in hardware. In one or more other embodiments, the untrained calibration engine 120 and/or the untrained ML model 125 can be implemented in software, for example using a computer 90 as shown in FIG. 9 according to one or more embodiments. The computer 90 includes one or more microprocessors (e.g., hardware-based microprocessors) 910, non-volatile computer memory 920, and volatile computer memory 930. The processor(s) 910 is/are in electrical communication with the non-volatile computer memory 920 and the volatile computer memory 930. The untrained ML model 125 can be stored in the non-volatile computer memory 920. The processor(s) 910 can run and/or execute instructions, such as software and/or firmware, that can train the untrained ML model 125 as described herein. The inputs to the untrained ML model 125, such as D_{ADC} and D_{REF}, can be temporarily stored in the volatile computer memory 930. Additionally or alternatively, intermediate calculations, such as the inputs and/or outputs of intermediate nodes or layers in the untrained ML model 125, can be temporarily stored in the volatile computer memory 930.

An ANN includes weights, biases, and has multiple (e.g., two or more) layers. The ANN operates on an input signal (in this case the digital output D_{ADC}) and then uses several activation layers to model a generalized polynomial. The output of the network can embed various types of information, depending on the target use case.

Although the topology of the neural network is selected ahead of time, the weights and biases are not. These are calculated by training the neural network. In supervised training, a known good outcome (in this case the digital output D_{REF}) is used to adjust the weights and biases, in order to minimize the error between the output of the network and this known good outcome. This training can be implemented with backpropagation techniques.

In one example, we use a fully connected ANN with several layers. The input to the network can be or include the digital output D_{ADC}. In other embodiments, the inputs to the network can be or include the past N samples of the digital output D_{ADC} which can allow more dynamic information to be captured. In other embodiments, the inputs to the network can be or include other types of information from the primary ADC 100 such as time-derivative information (e.g., the time derivative of the input voltage V_{IN} and/or of the digital output D_{ADC}).

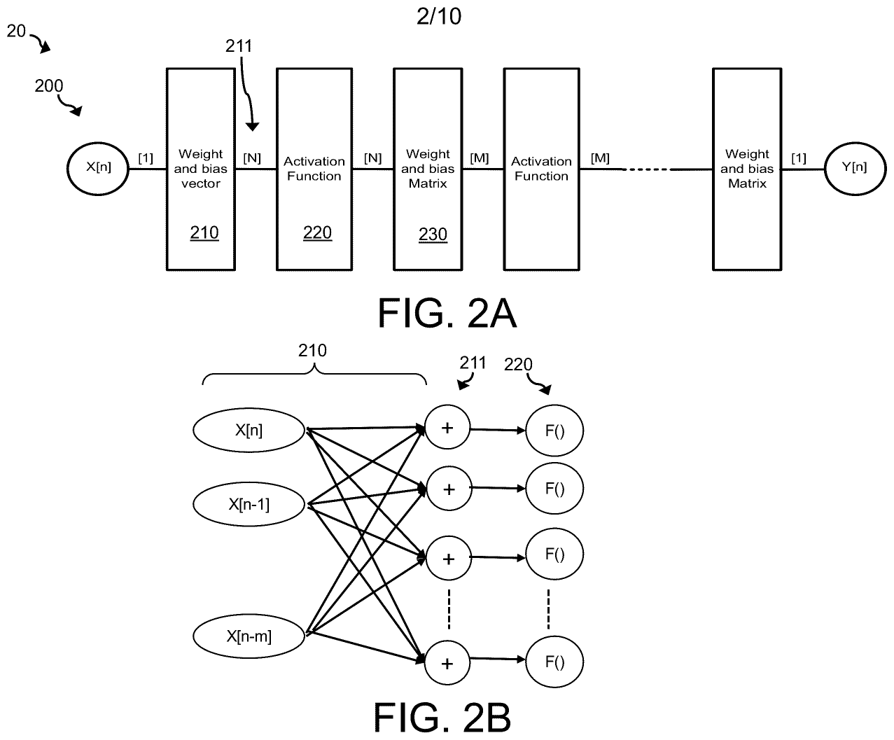

FIG. 2A is a block diagram of a fully connected ANN 20 according to one or more embodiments. Here, the digital output D_{ADC}, represented as X[n] (reference number 200) in FIG. 2, is multiplied with weights, at 210, into a vector of 1×N, generating another vector at 211. This goes into an activation function 220, the output of which is then multiplied by a weight and bias matrix of N×M at 230. This repeats until the signal traverses through all the layers, before finally being combined into a signal output Y[n] which represents the corrected digital output (e.g., D_{OUT} in FIG. 1) of the calibration engine 120. An example expanded view of reference numbers 210, 211, and 220 is shown in FIG. 2B.

The activation function 220 can include one of several different functions. The activation function 230 can inject a nonlinearity into the ANN 20. The ANN 20 can include one activation function 220 or multiple activation functions 220, where each activation function 220 can be the same as of different than one or more other activation function(s). In one or more embodiments, the activation function 220 can be or include a rectified linear unit (RELU) function, which can be implemented in hardware. A RELU function simply sets the output to 0 if its input is less than zero, and its output to its input if it is larger than 0. Specifically:

$$\begin{matrix}Z = RELU [ X ] = 0 for x < 0 , and \\ Z = RELU [ X ] = x for x \geq 0 ,\end{matrix}$$

where in this embodiment X is the digital output D_{ADC} of the primary ADC 100 and Z is the output of the activation function 220.

The number of layers and the size of each layer in the ANN 20 are selected ahead of time. However, the impairments that this network can correct for are not specified. For example, the same ANN can compensate for offset error, gain error, and/or nonlinearities, and can be modified to also correct for dynamic errors, memory effects, capacitor errors (in successive-approximation register (SAR) ADCs, for example), etc. For example, to correct dynamic errors, we can provide m samples of the digital output D_{ADC} in addition to the current digital output (e.g., X[N], X[N-1], X[N-2] . . . . X[N-m] instead of just X[N] as in FIG. 2A) as inputs to the ANN 20. The m samples of the digital output D_{ADC} can be stored in one or more buffers (such as a series of D-flipflops) and then provided as inputs the ML model. To correct capacitor errors, such as in SAR ADCs, we can provide the raw comparator outputs instead of just D_{ADC} (which is the combination of the comparator outputs) as inputs to the ANN 20. The raw comparator outputs can be stored in one or more buffers and then provided as inputs the ML model.

In the initial state, the weights and biases of the ANN 20 can be set to 0 or to arbitrary pre-determined values. As the primary and reference ADCs 100, 110 run during training, backpropagation tunes the values of the weights and biases to minimize the error between the output 104 of the primary ADC 100 (i.e., D_{ADC}) and the output 114 of the reference ADC 110 (i.e., D_{REF}), for example using gradient descent, in supervised learning. This tuning can happen in the background (which can operate based on the input signal statistics), or in the foreground (which can ensure that the entire signal range is covered). In one or more embodiments, tuning can initially begin with foreground calibration, such that the network training converges faster, with background calibration used to update the network parameters as a function of ambient conditions.

In foreground calibration, the input voltage V_{IN} can be produced by a voltage source such that the input voltage V_{IN} is known and controllable. The expected digital value of the input voltage V_{IN} can be input to the untrained calibration engine 120. Alternatively, the output of a reference ADC 100 can be input to the untrained calibration engine 120 (e.g., as illustrated in FIG. 1). In background calibration, the input voltage V_{IN} is unknown, for example when the input voltage V_{IN} is produced by a larger circuit or system. In background calibration, the output of a reference ADC 100 can be input to the untrained calibration engine 120 (e.g., as illustrated in FIG. 1).

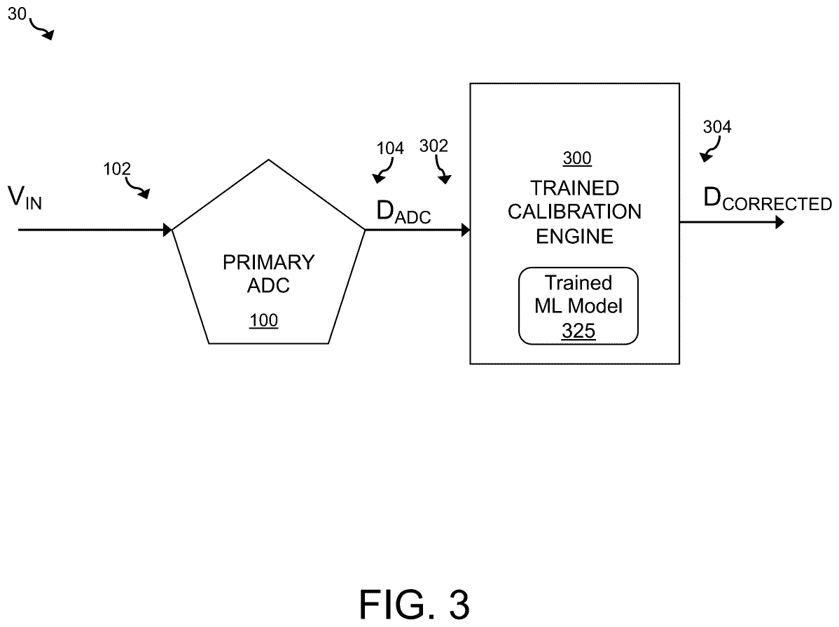

FIG. 3 is a block diagram of a system 30 for performing an analog-to-digital conversion of an input voltage V_{IN} to a corrected digital output D_{CORRECTED} using a trained calibration engine 300 according to one or more embodiments. System 30 is the same as system 10 except that in system 30 the untrained calibration engine 120 is replaced with a trained calibration engine 300 and the reference ADC 110 is removed. The trained calibration engine 300 includes a trained ML model 325, such as a trained ANN, that was trained as described herein. The digital output D_{ADC} of the primary ADC 100 is provided as an input 302 to the trained calibration engine 300. The trained calibration engine 300 processes the digital output D_{ADC} and produces, at an output 304, a corrected digital output D_{CORRECTED} that is more accurate than the digital output D_{ADC} and can account for more variables, including dynamic variables/non-linearities, compared to conventional calibration methods, such as using lookup tables (LUTs).

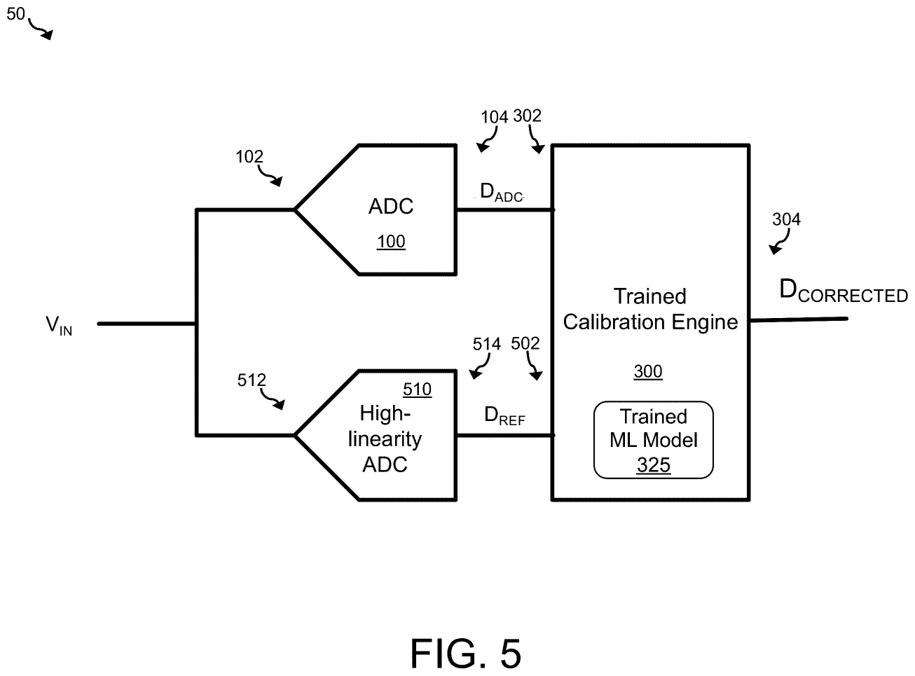

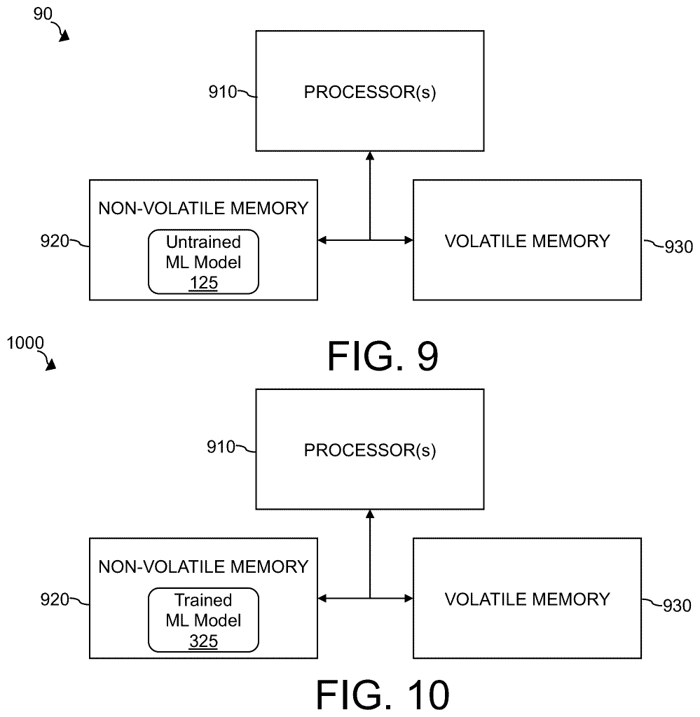

In one or more embodiments, the trained calibration engine 300 and/or the trained ML model 325 can be implemented in hardware. In one or more other embodiments, the trained calibration engine 300 and/or the trained ML model 325 can be implemented in software, for example using a computer 1000 as shown in FIG. 10 according to one or more embodiments. The computer 1000 is the same as the computer 90 except that the non-volatile memory 920 in computer 1000 stores a trained ML 325 instead of an untrained ML model 125 which is stored in the non-volatile memory 920 of the computer 90. The input(s) to the trained ML model 325, such as D_{ADC} and optionally D_{REF} (e.g., as discussed with respect to FIG. 5), can be temporarily stored in the volatile computer memory 930. Additionally or alternatively, intermediate calculations, such as the inputs and/or outputs of intermediate nodes or layers in the trained ML model 325, can be temporarily stored in the volatile computer memory 930.

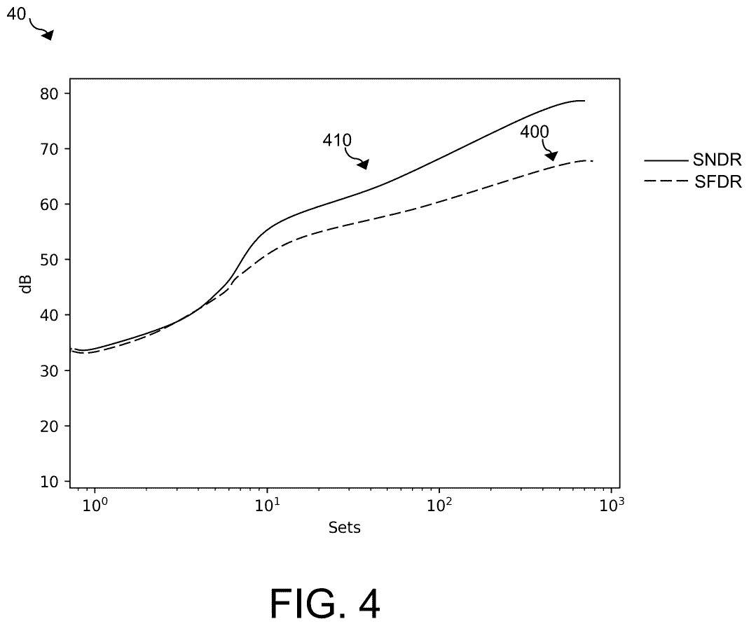

FIG. 4 is an example graph 40 of the spurious-free dynamic range (SFDR) 400 and signal-to-noise and distortion ratio (SNDR) 410 convergence from a simulation of an ANN that was trained as described above. The ANN was trained using an example 12-bit primary ADC as an input. In the graph 40, each set on the horizontal axis consists of 10,000 samples. An ideal 12-bit ADC theoretically provides a 73 dB peak SNDR and a 93 dB peak SFDR. The primary ADC with uncorrected nonlinear errors has a peak SFDR and SNDR of 56 dB and 54 dB, respectively. At the beginning of training, the trained ANN output (e.g., the corrected digital output D_{CORRECTED} (FIG. 4)) has an SFDR 400 and SNDR 410 of about 34 dB, and ends up at an SFDR of 82 dB and an SNDR of 69 dB, which results in a 15 dB improvement in the SNDR and a 26 dB improvement in the SFDR compared to those of the uncorrected output of the primary ADC.

FIG. 5 is a block diagram of a system 50 for performing an analog-to-digital conversion of an input voltage V_{IN} to a corrected digital output D_{CORRECTED} using a trained calibration engine 300 according to one or more alternative embodiments. System 50 is the same as system 30 except that in system 50 a reference ADC 510 is included. The reference ADC 510 can be the same as or different than the reference ADC 110. The input 512 of the reference ADC 510 is electrically connected to the input voltage V_{IN} and the output 514 of the reference ADC 510 is electrically connected to a second input 502 of the trained calibration engine 300. The output 104 of the primary ADC 100 is electrically connected to a first input 302 of the trained calibration engine 300. The trained calibration engine 300 receives the digital outputs D_{ADC} and D_{REF} at the first and second inputs 302, 502, respectively of the trained calibration engine 300.

The reference ADC 510 can be used to provide additional calibration of the primary ADC 100. For example, the output 514 of the reference ADC 510 can be used for background calibration of temperature drift of the primary ADC 100, supply changes, aging, and/or changes in ambient conditions. The trained calibration engine 300 would operate by updating the trained ML model 325, such as the weights of the trained ML model 325, as the trained calibration engine 300 receives more data, using backpropagation. The trained ML model 325 can be updated in response to one or more hardware register controls.

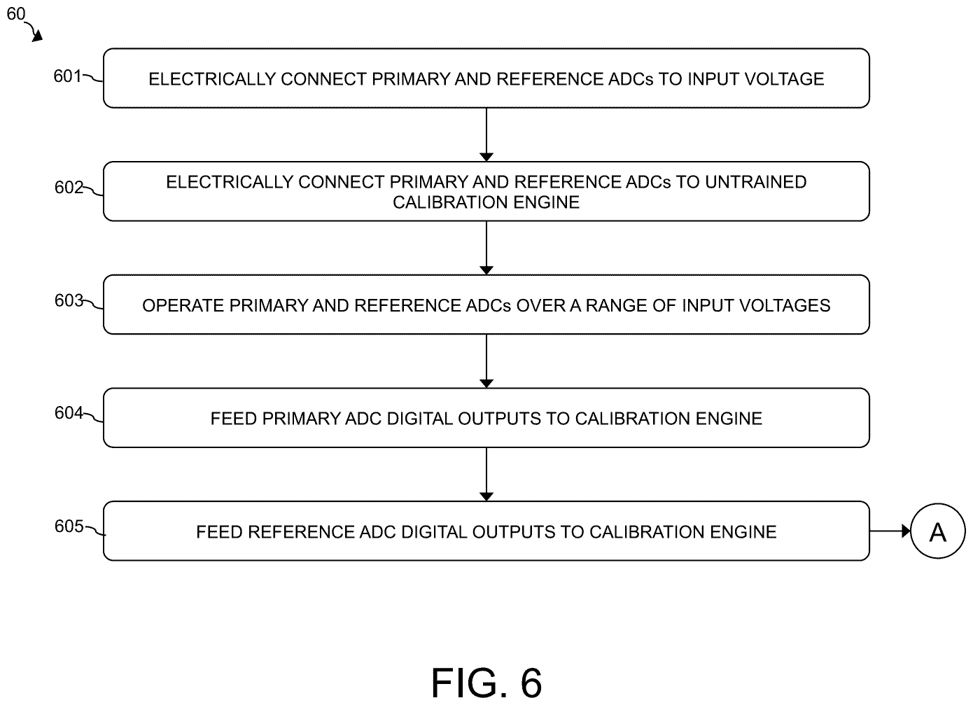

FIG. 6 is a flow chart of a method 60 for training a calibration engine for an ADC according to one or more embodiments.

In step 601, the input 102 of a primary ADC 100 and the input 112 of a reference ADC 110 are electrically connected to an (e.g., the same) input voltage V_{IN}. The input voltage V_{IN} can be a DC voltage or an AC voltage. The input voltage V_{IN} can be produced as part of a larger circuit that can provide functionality for at least a portion of an electronic device. Alternatively, the input voltage V_{IN} can be produced by a voltage source such that the input voltage V_{IN} is known and controlled.

In step 602, the output 104 of the primary ADC 100 and the output 114 of the reference ADC 110 are electrically connected to respective inputs 121, 122 of an untrained calibration engine 120. The untrained calibration engine 120 includes an untrained ML model 125 such as an untrained ANN. The untrained ML model 125 has a predetermined topology, such as a predetermined number of layers, a predetermined number and/or type of activation function(s), and/or other features of the untrained ML model.

In step 603, the primary and reference ADCs 100, 110 are operated over a range of input voltages V_{IN}. For example, the primary and reference ADCs 100, 110 can be operated over all or substantially all (e.g., 95% to 99%) of the operating range of the primary and reference ADCs 100, 110. During operation, the primary and reference ADCs 100, 110 sample the input voltage V_{IN} at respective first and second frequencies, and convert the sampled input voltages V_{IN} to digital outputs D_{ADC} and D_{REF}, respectively.

In step 604, the digital outputs D_{ADC} of the primary ADC 100 are fed to the first input 121 of the untrained calibration engine 120.

In step 605, the digital outputs D_{REF} of the reference ADC 110 are fed to the second input 122 of the untrained calibration engine 120.

In step 606 (via placeholder A), the untrained ML model 125 in the untrained calibration engine 120 is trained using the digital outputs D_{ADC} and D_{REF} to form a trained ML model 325 and a trained calibration engine 300. The untrained ML model 125 uses the digital output D_{REF} as ground truth during supervised training. The untrained ML model 125 can be trained using background calibration when the input voltages V_{IN} are produced as part of a larger circuit. Alternatively, the untrained ML model 125 can be trained using foreground calibration when the input voltages V_{IN} are produced by a voltage source. The untrained ML model 125 can be trained and/or optimized using a gradient descent algorithm and/or another technique.

In optional step 607, the trained ML model 325 can be stored such as in non-volatile memory (e.g., non-volatile memory 930 (FIG. 10)) operably coupled to the primary ADC output 104. Additionally or alternatively, one or more registers of a trained ML model 325 can be updated, for example, when the trained ML model 325 is implemented in hardware.

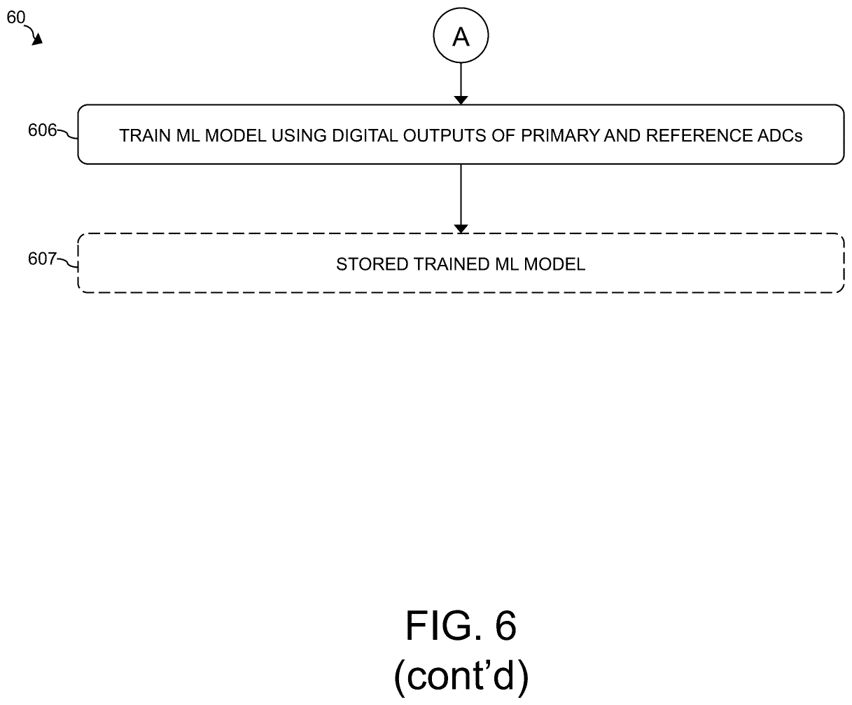

FIG. 7 is a flow chart of a method 70 for correcting a digital output of an ADC using a trained calibration engine according to one or more embodiments.

In step 701, the input 102 of a primary ADC 100 is electrically connected to an input voltage V_{IN}. The input voltage V_{IN} can be a DC voltage or an AC voltage. The input voltage V_{IN} can be produced as part of a larger circuit that can provide functionality for at least a portion of an electronic device. Alternatively, the input voltage V_{IN} can be produced by a voltage source such that the input voltage V_{IN} is known and controlled.

In step 702, the output 104 of the primary ADC 100 is electrically connected to an input 302 of a trained calibration engine 300. The trained calibration engine 300 includes a trained ML model 325 such as a trained ANN.

In step 703, the primary ADC 100 is operated to sample and convert the input voltage V_{IN} to a digital output D_{ADC} that has a digital value that represents the sampled input voltage V_{IN}.

In step 704, the trained ML model 325 corrects the digital output D_{ADC} of the primary ADC 100. The trained ML model 325 can correct for known and unknown nonlinearities in the primary ADC 100 to provide a more linear digital output (e.g., a higher SFDR) than would be possible using prior art LUTs.

In step 705, the trained calibration engine 300 outputs a corrected digital output D_{CORRECTED} for the primary ADC 100.

In one or more embodiments, steps 703-705 can be repeated such as at the operating frequency (e.g., the first frequency) of the primary ADC 100.

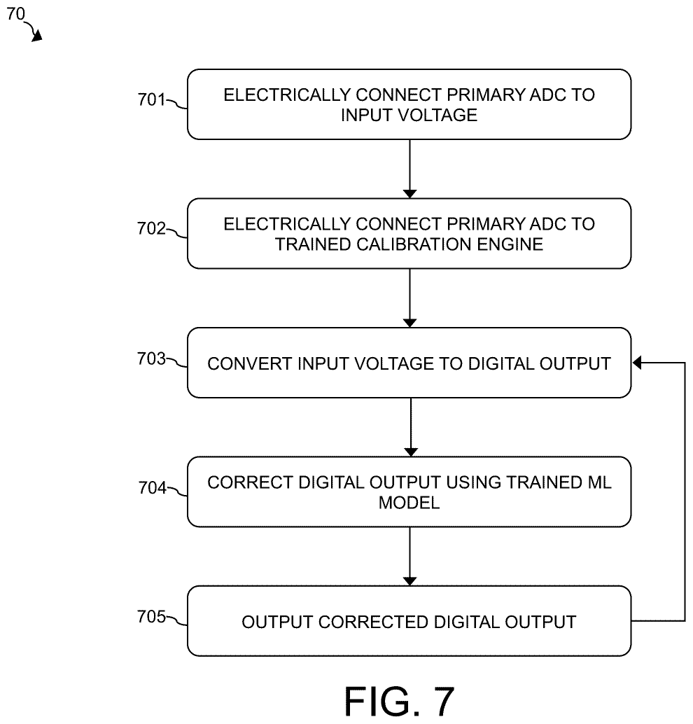

FIG. 8 is a flow chart of a method 80 for correcting a digital output of an ADC using a trained calibration engine according to one or more alternative embodiments.

In step 801, the input 102 of a primary ADC 100 and the input 512 of a reference ADC 510 are electrically connected to an (e.g., the same) input voltage V_{IN}. The input voltage V_{IN} can be a DC voltage or an AC voltage. The input voltage V_{IN} can be produced as part of a larger circuit that can provide functionality for at least a portion of an electronic device. Alternatively, the input voltage V_{IN} can be produced by a voltage source such that the input voltage V_{IN} is known and controlled.

In step 802, the output 104 of the primary ADC 100 and the output 514 of the reference ADC 510 are electrically connected to respective inputs 302, 502 of a trained calibration engine 300. The trained calibration engine 300 includes a trained ML model 325 such as a trained ANN.

In step 803, the primary and reference ADCs 100, 510 are operated to sample and convert the input voltage V_{IN} to respective digital outputs D_{ADC}, D_{REF}. The digital outputs D_{ADC}, D_{REF} have has respective digital values that represent the sampled input voltage V_{IN}.

In step 804, the trained ML model 325 corrects the digital output D_{ADC} of the primary ADC 100. The trained ML model 325 can correct for known and unknown nonlinearities in the primary ADC 100 to provide a more linear digital output (e.g., a higher SFDR) than would be possible using prior art LUTs.

In step 805, the trained calibration engine 300 outputs a corrected digital output D_{CORRECTED} for the primary ADC 100.

In step 806, the trained ML model 325 is updated using the outputs D_{REF} of the reference ADC 510 and the outputs D_{ADC} of the primary ADC 100. For example, the outputs D_{REF} of the reference ADC 510 can be used for background calibration of temperature drift of the primary ADC 100, supply changes, aging, and/or changes in ambient conditions. One or more weights of the trained ML model 325 can be updated, using backpropagation, as the trained calibration engine 300 receives more data from the primary and reference ADCs 100, 510. The outputs D_{REF} of the reference ADC 510 are used as ground-truth data for updating the trained ML model 325.

In one or more embodiments, steps 803-805 can be repeated such as at the operating frequency (e.g., the first frequency) of the primary ADC 100, at the operating frequency (e.g., the second frequency) of the reference ADC 510, or at another frequency. Step 806 can be repeated on a regular or irregular basis or frequency, for example as needed.

The invention should not be considered limited to the particular embodiments described above. Various modifications, equivalent processes, as well as numerous structures to which the invention may be applicable, will be readily apparent to those skilled in the art to which the invention is directed upon review of this disclosure. The above-described embodiments may be implemented in numerous ways. One or more aspects and embodiments involving the performance of processes or methods may utilize program instructions executable by a device (e.g., a computer, a processor, or other device) to perform, or control performance of, the processes or methods.

In this respect, various inventive concepts may be embodied as a non-transitory computer readable storage medium (or multiple non-transitory computer readable storage media) (e.g., a computer memory of any suitable type including transitory or non-transitory digital storage units, circuit configurations in Field Programmable Gate Arrays or other semiconductor devices, or other tangible computer storage medium) encoded with one or more programs that, when executed on one or more computers or other processors, perform methods that implement one or more of the various embodiments described above. When implemented in software (e.g., as an app), the software code may be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone or any other suitable portable or fixed electronic device.

Also, a computer may have one or more communication devices, which may be used to interconnect the computer to one or more other devices and/or systems, such as, for example, one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Also, a computer may have one or more input devices and/or one or more output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

The non-transitory computer readable medium or media may be transportable, such that the program or programs stored thereon may be loaded onto one or more different computers or other processors to implement various one or more of the aspects described above. In some embodiments, computer readable media may be non-transitory media.

The terms “program,” “app,” and “software” are used herein in a generic sense to refer to any type of computer code or set of computer-executable instructions that may be employed to program a computer or other processor to implement various aspects as described above. Additionally, it should be appreciated that, according to one aspect, one or more computer programs that when executed perform methods of this application need not reside on a single computer or processor but may be distributed in a modular fashion among a number of different computers or processors to implement various aspects of this application.

Computer-executable instructions may be in many forms, such as program modules, executed by one or more computers or other devices. Generally, program modules include routines, programs, objects, components, data structures, etc. that performs particular tasks or implement particular abstract data types. The functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Thus, the disclosure and claims include new and novel improvements to existing methods and technologies, which were not previously known nor implemented to achieve the useful results described above. Users of the method and system will reap tangible benefits from the functions now made possible on account of the specific modifications described herein causing the effects in the system and its outputs to its users. It is expected that significantly improved operations can be achieved upon implementation of the claimed invention, using the technical components recited herein.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

1. A system comprising:
a primary analog-to-digital converter (ADC) having an input electrically coupled to an input voltage, the primary ADC configured to sample the input voltage at a frequency and convert sampled input voltages to respective primary ADC digital outputs; and
a trained calibration engine having an input electrically coupled to an output of the primary ADC, the trained calibration engine including a trained machine-learning (ML) model configured to correct each primary ADC digital output to a respective corrected digital output, the trained ML model having been trained with reference digital outputs from a reference ADC and training digital outputs from the primary ADC, the reference digital outputs representing ground-truth data for modeling the training digital outputs from the primary ADC.

2. The system of claim 1, wherein the reference ADC comprises a sigma-delta ADC.

3. The system of claim 1, wherein the frequency of the primary ADC is higher than a frequency of the reference ADC.

4. The system of claim 3, wherein the frequency of the primary ADC is about 50 times to about 1,000 higher than the frequency of the reference ADC.

5. The system of claim 4, wherein the frequency of the primary ADC is about 1 gigasamples per second (GSPS) to about 100 GSPS.

6. The system of claim 1, wherein the trained ML model comprises a trained artificial neural network.

7. A system comprising:
a primary analog-to-digital converter (ADC) having an input electrically coupled to an input voltage, the primary ADC configured to sample the input voltage at a first frequency and convert first sampled input voltages to respective primary ADC digital outputs;
a reference ADC having an input electrically coupled to the input voltage, the reference ADC configured to sample the input voltage at a second frequency and convert second sampled input voltages to respective second ADC digital outputs; and
a trained calibration engine having a first input electrically coupled to an output of the primary ADC and a second input electrically coupled to an output of the reference ADC, the trained calibration engine including a trained machine-learning (ML) model configured to correct the primary ADC digital output to a corrected digital output, the trained ML model having been trained with reference digital outputs from the reference ADC and training digital outputs from the primary ADC, the reference digital outputs representing ground-truth data for modeling the training digital outputs from the primary ADC, the trained calibration engine configured to update the trained ML model using the respective second ADC digital outputs.

8. The system of claim 7, wherein the reference ADC comprises a sigma-delta ADC.

9. The system of claim 7, wherein the first frequency of the primary ADC is higher than the second frequency of the reference ADC.

10. The system of claim 9, wherein the first frequency of the primary ADC is about 50 times to about 1,000 higher than the second frequency of the reference ADC.

11. The system of claim 10, wherein the first frequency of the primary ADC is about 1 gigasamples per second (GSPS) to about 100 GSPS.

12. The system of claim 7, wherein the trained ML model comprises a trained artificial neural network.

13. A method for training a calibration engine for a primary analog-to-digital converter (ADC), comprising:
electrically connecting an input of the primary ADC to an input voltage, the primary ADC configured to sample the input voltage at a first frequency and convert first sampled input voltages to respective primary ADC digital outputs;
electrically connecting an input of a reference ADC to the input voltage, the reference ADC configured to sample the input voltage at a second frequency and convert second sampled input voltages to respective reference ADC digital outputs;
electrically connecting an output of the primary ADC to a first input of the calibration engine, the calibration engine including an untrained machine-learning (ML) model;
electrically connecting an output of the reference ADC to a second input of the calibration engine;
operating the primary and reference ADCs over an input-voltage range;
feeding the respective primary ADC digital outputs to the calibration engine, the respective primary ADC digital outputs representing the input-voltage range;
feeding the respective reference ADC digital outputs to the calibration engine, the respective reference ADC digital outputs representing the input-voltage range; and
training the untrained ML model in the calibration engine using the respective primary ADC digital outputs and the respective reference ADC digital outputs, the respective reference ADC digital outputs representing ground-truth data for modeling the respective primary digital outputs from the primary ADC.

14. The method of claim 13, further comprising producing the input voltage with a voltage source such that the input voltage is known.

15. The method of claim 14, wherein the untrained ML model is trained using foreground calibration.

16. The method of claim 13, wherein the input voltage is unknown and the untrained ML model is trained using background calibration.

17. The method of claim 13, wherein the reference ADC comprises a sigma-delta ADC.

18. The method of claim 13, wherein the first frequency of the primary ADC is higher than the second frequency of the reference ADC.

19. The method of claim 18, wherein the first frequency of the primary ADC is about 1 gigasamples per second (GSPS) to about 100 GSPS.

20. The system of claim 13, wherein the untrained ML model comprises an untrained artificial neural network.
